(19) United States
(12) Patent Application Publication
(10) Pub. No.: US 2005/0083667 A1
(43) Pub. Date: Apr. 21, 2005

(54) COMPUTER SYSTEM

(76) Inventors: Chun-Chang Lai, Taipei City (TW); Chun-Lung Yu, Taipei City (TW)

Correspondence Address: NORTH AMERICA INTERNATIONAL PATENT OFFICE (NAIPC), P.O. BOX 506, MERRIFIELD, VA, 22116, US

(21) Appl. No.: 10/707,718

(22) Filed: Jan. 6, 2004

(30) Foreign Application Priority Data
Oct. 21, 2003 (TW) 092218693

(51) Int. Cl. H05K 7/14; H05K 7/18

(52) U.S. Cl. 361/797

(57) ABSTRACT

A computer system has a housing, a motherboard installed inside the housing, a cage installed on a region inside the housing and adjacent to a top surface of the motherboard, and at least an integrated drive electronics device installed inside the cage. The motherboard has the top surface, a bottom surface, and a central processing unit installed on the bottom surface for processing data.

### BACKGROUND OF INVENTION

1. Field of the Invention

The present invention relates to a computer system, and more particularly, to a computer system having a motherboard, a central processing unit installed on a bottom surface of the motherboard, and at least an integrated drive electronics device installed on top of the motherboard.

2. Description of the Prior Art

Please refer to FIG. 1, which is a schematic diagram of an ATX computer system 10 according to the prior art. The computer system 10 comprises a housing 12, a motherboard 14 installed inside the housing 12, a central processing unit (CPU) 15 installed on the motherboard 14, five peripheral component interconnect (PCI) slots 16 installed on the motherboard 14 and electrically connected to the CPU 15, a plurality of integrated drive electronics (IDE) connectors 18 installed on the motherboard 14, a power supply 20, and a plurality of IDE devices 22 and 24.

In contrast to an old model AT computer system, such as a baby AT or a BAT, the ATX computer system 10 has a characteristic that the layout between the CPU 15 and the PCI slots 16 has been rotated by 90 degrees so that additional space is created to accommodate more full-length added cards.

Please refer to FIG. 2, which is a schematic diagram of an NLX computer system 30 according to the prior art. The computer system 30 comprises a housing 32, a motherboard 34 installed inside the housing 32, a CPU 35 installed on the motherboard 34, a riser connector 36 installed on the motherboard 34 and having 340 pins, a riser card 38 plugged into the riser connector 36, a power supply 40, and a plurality of add-in card slots (not shown) installed on the riser card 38 for electrically connecting with a plurality of IDE devices.

The NLX computer system 30 can be manually opened without any tools. Moreover, the motherboard 34 of the NLX computer system 30 is installed on a track-like frame and can be easily slid away from the frame for maintenance.

Since a CPU in operation always generates heat and too much the heat affects the CPU, the ATX computer system 10 and the NLX computer system 30 both have to reserve a specific space on top of the CPU 15 (CPU 35) for ventilating heat generated by the CPU 15. The specific space increases the bulk of the ATX computer system 10.

In addition to the CPU 15, IDE devices such as a hard disk drive (HDD) in the ATX computer system 10 generate heat too. According to the ATX 10 and the NLX computer system 30 standards, the IDE devices are also installed on the motherboard 14 surrounding the CPU 15. Therefore, heat generated by the CPU 15 will affect the IDE devices and vice versa, and the ATX computer system 10 easily suffers malfunctions.

### SUMMARY OF INVENTION

It is therefore a primary objective of the claimed invention to provide a computer system protected from heat interference and having a small bulk.

According to the claimed invention, the computer system has a housing, a motherboard installed inside the housing, a cage installed on a region inside of the housing and adjacent to a top surface of the motherboard, and at least an integrated drive electronics device installed inside the cage. The motherboard has the top surface, a bottom surface, and a central processing unit installed on the bottom surface for processing data.

In the preferred embodiment of the present invention, the housing has at least a first heat-ventilating hole installed on top of the motherboard, at least a second heat-ventilating hole installed on bottom of the motherboard, a first heat-ventilating device corresponding to the first heat-ventilating hole for ventilating heat generated by the IDE devices via the first heat-ventilating hole to a first region outside of the housing, and a second heat-ventilating device corresponding to the second heat-ventilating hole for ventilating heat generated by the CPU via the second heat-ventilating hole to a second region outside of the housing.

The computer system further has at least a memory slot obliquely installed on the bottom surface of the motherboard.

Since the computer system has the IDE devices installed on top of the motherboard and the CPU installed on the bottom surface of the motherboard, the computer system is protected from heat interference. Moreover, the computer system does not need to have a specific space reserved for heat-ventilation and therefore has a smaller size.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of an ATX computer system according to the prior art.

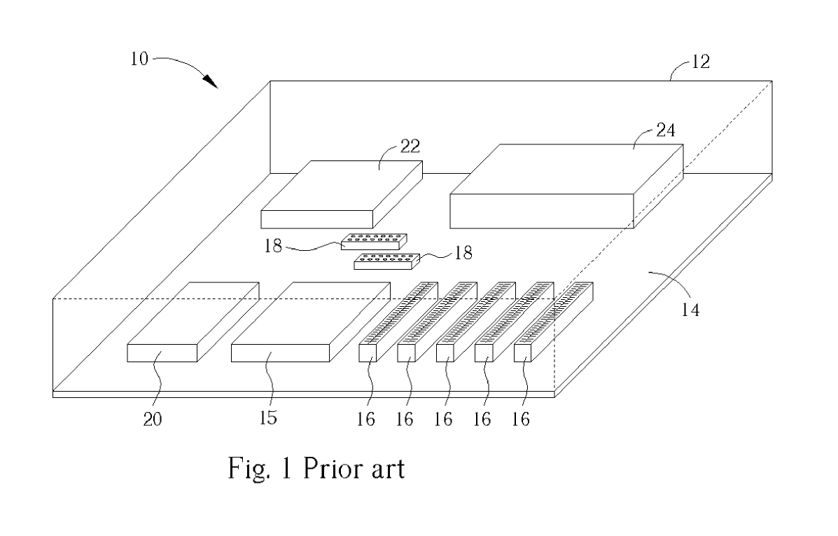

FIG. 2 is a schematic diagram of an NLX computer system according to the prior art.

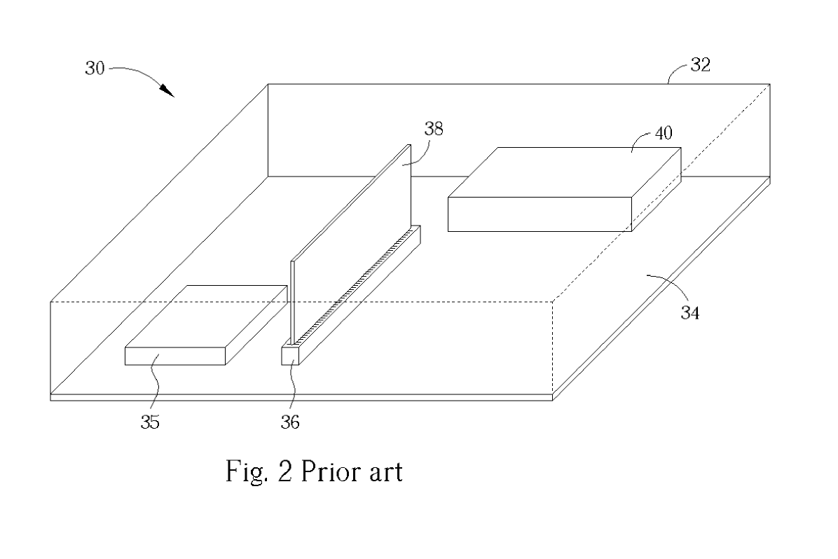

FIG. 3 is an exploded view of a computer system of a preferred embodiment according to the present invention.

FIG. 4 is a fabrication diagram of a motherboard, a motherboard cage and a cage of the computer system shown in FIG. 3 according to the present invention.

### DETAILED DESCRIPTION

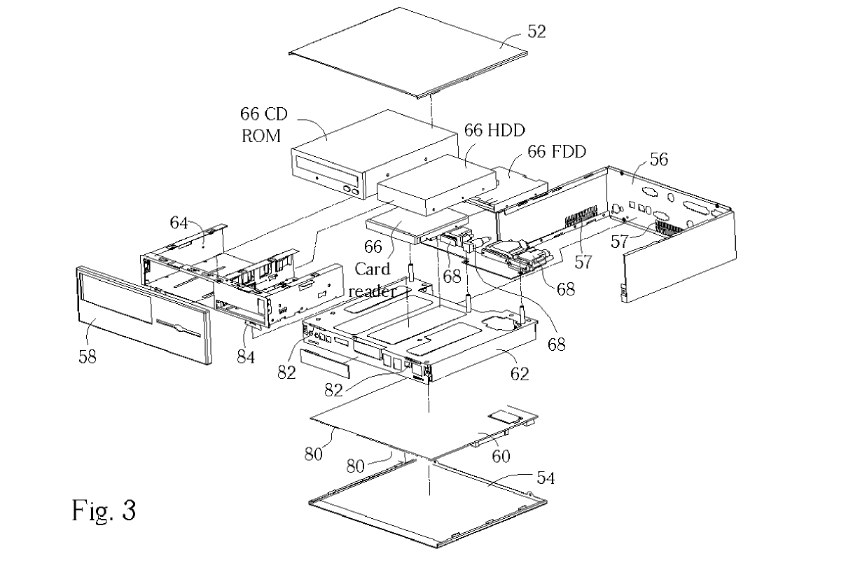

Please refer to FIG. 3, which is an exploded view of a computer system 50 of a preferred embodiment according to the present invention. The computer system 50 comprises a top housing 52, a bottom housing 54, a rear housing 56, at least a second heat-ventilating hole 57 installed on the rear housing 56, a panel 58, a motherboard 60 installed inside a housing consisting of the top housing 52, the bottom housing 54 and the rear housing 56, a motherboard cage 62 installed on a top surface of the motherboard 60 for accommodating the motherboard 60, a cage 64 installed on top of the motherboard cage 62, a plurality of IDE devices 66 installed inside the cage 64 such as a HDD, a card reader, a CD-ROM and a floppy disk drive (FDD), a plurality of seldom-used headers 68 fixed on the motherboard cage 62, and at least a second heat-ventilating device (not shown) installed inside the cage 64 for ventilating heat generated by the IDE devices 66 in operation via the second heat-ventilating hole 57 to a region outside of the housing.

The motherboard cage 62 comprises a positioning hole 82 and the cage 64 comprises a positioning device 84 corresponding to the positioning hole 82 for positioning the cage 64 onto the motherboard cage 62 by plugging into the positioning hole 82 of the motherboard cage 62 when the cage 64 is placed on top of the motherboard cage 62.

In the preferred embodiment of the present invention, the second heat-ventilating device is a fan cooler, the headers 68 include two Sonic/Philips Digital Interface Format (SPDIF in/out) headers, an S-video header, a VGA output header, and two DC output headers, etc., and the top housing 52, the bottom housing 54 and the panel 58 can be all fixed to the rear housing 58 by the use of screws.

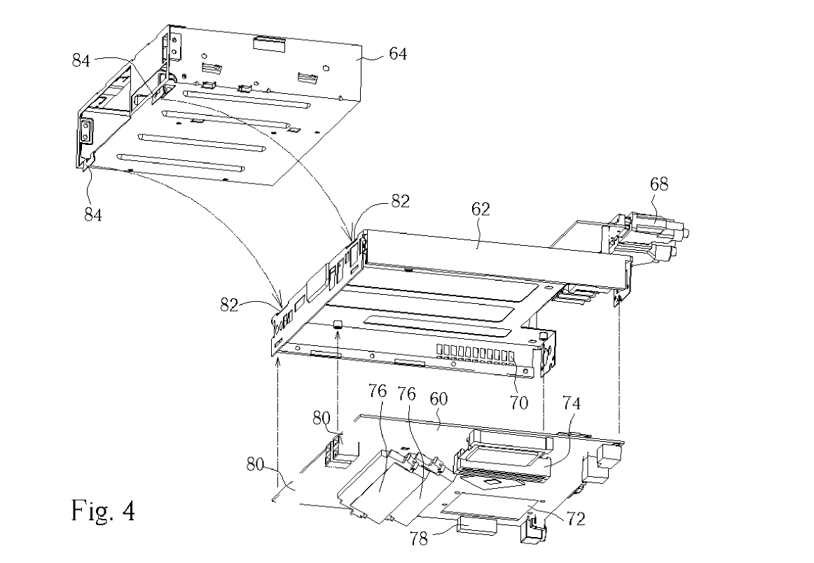

Please refer to FIG. 4, which is a fabrication diagram of the motherboard 60, the motherboard cage 62 and the cage 64 of the computer system 50 shown in FIG. 3 according to the present invention. The motherboard cage 62 comprises at least a first heat-ventilating hole 70. The motherboard 60 comprises a bottom surface, a CPU 72 installed on the bottom surface, at least an add-in card slot 74 for an accelerated graphic port (AGP) card or a PCI card to be plugged into, at least a memory slot 76 obliquely installed on the bottom surface, a plurality of frequently-used headers 80, and a first heat-ventilating device 78 adjacent to the CPU 72 for ventilating heat generated by the CPU 72 in operation via the first heat-ventilating hole 70 to a region outside of the housing.

In the preferred embodiment of the present invention, the first heat-ventilating device 78 is a pipeline cooler, the memory slot 76 and the motherboard 60 have an included angle of 65 degrees, the headers 80 include IDE headers capable of electrically connecting the IDE devices 66 with electronic devices outside of the computer system 50, two digital audio output/input headers, two four/six-pin IEEE 1394 headers, etc. In order to reduce the bulk of the computer system 50 further, the memory slot 76 can be flatly installed on the motherboard 60 and the include angle between the memory slot 76 and the motherboard 60 can approach zero degrees to confine the memory slot 76 to a height lower than that of the CPU 72.

In contrast to the prior art computer systems, the computer system 50 of the present invention has at least the following advantages:

1. Since the CPU 72 is installed on the bottom surface of the motherboard 60 and the cage 64 is installed on top of the motherboard 60, the computer system 60 does not have to have the specific space reserved for ventilating heat generated by the CPU 72 in operation and thus has a small size;

2. Since the cage 64 is installed on top of the motherboard 60 and the CPU 72 is installed on the bottom surface of the motherboard 60, the IDE devices 66 inside the cage 64 will not generate any heat that interferes with the CPU 72 and vice versa;

3. Since the top housing 52 and the bottom housing 54 are detachable from the rear housing 56, maintenance workers can remove the top housing 52 from the rear housing 56 and maintain the IDE devices 66 inside the cage 64 or remove the bottom housing 54 from the rear housing 56 and maintain electronic components such as the CPU 72 and the memory slot 76 on the bottom surface of the motherboard 60; and

4. The cage 64 is not fixed to but positioned on the motherboard cage 62 and can be therefore easily separated from the motherboard cage 62 for the convenience of maintaining the IDE devices 66.

Following the detailed description of the present invention above, those skilled in the art will readily observe that numerous modifications and alterations of the device may be made while retaining the teachings of the invention. Accordingly, the above disclosure should be construed as limited only by the metes and bounds of the appended

1. A computer system comprising:
a housing;
a motherboard installed inside the housing, the motherboard comprising:
a top surface;
a bottom surface; and
a central processing unit installed on the bottom surface for processing data;
a cage installed on a region inside of the housing and adjacent to the top surface of the motherboard; and
at least an integrated drive electronics device installed inside the cage.

2. The computer system of claim 1 further comprising a first heat-ventilating device installed on a region inside of the housing and adjacent to the bottom surface of the motherboard for ventilating heat generated by the central processing unit to a region outside of the housing.

3. The computer system of claim 1, wherein the first heat-ventilating device is a pipeline cooler.

4. The computer system of claim 2 further comprising at least a first heat-ventilating hole installed on the housing and adjacent to the bottom surface of the motherboard, the first heat-ventilating device ventilating heat generated by the central processing unit through the first heat-ventilating hole and to a region outside of the housing.

5. The computer system of claim 1 further comprising a second heat-ventilating device installed on a region inside of the housing and adjacent to the top surface of the motherboard for ventilating heat generated by the integrated drive electronics device to a region outside of the housing.

6. The computer system of claim 5, wherein the second heat-ventilating device is a fan cooler.

7. The computer system of claim 5 further comprising at least a second heat-ventilating hole installed on the housing and adjacent to the top surface of the motherboard, the second heat-ventilating device ventilating heat generated by the integrated drive electronics device through the second heat-ventilating hole and to a region outside of the housing.

8. The computer system of claim 1 further comprising at least a memory slot.

9. The computer system of claim 8, wherein the memory slot is obliquely installed on the bottom surface of the motherboard.

10. The computer system of claim 9, wherein the obliquely installed memory slot has a height smaller than that of the central processing unit.

11. The computer system of claim 1 further comprising a motherboard cage installed on top of the top surface of the motherboard and beneath the cage.

12. The computer system of claim 11, wherein the motherboard cage comprises at least a positioning aperture and the cage comprises at least a positioning device corresponding to the positioning aperture for plugging into the positioning aperture when the cage is mounted on the motherboard cage.

13. The computer system of claim 11, wherein the motherboard cage comprises a plurality of connectors.

14. The computer system of claim 1, wherein the integrated drive electronics device is a hard disk drive.

15. The computer system of claim 1, wherein the integrated drive electronics device is a card reader.

16. The computer system of claim 1, wherein the integrated drive electronics device is a CD-ROM drive.

17. The computer system of claim 1, wherein the integrated drive electronics device is a floppy disk drive.

18. The computer system of claim 1, wherein the cage comprises a plurality of connectors.
